(19) United States
(12) Patent Application Publication
(10) Pub. No.: US 2019/0109092 A1
(43) Pub. Date: Apr. 11, 2019

(54) POSITIONING STRUCTURE HAVING POSITIONING UNIT

(71) Applicant: Siliconware Precision Industries Co., Ltd., Taichung (TW)

(72) Inventors: Rui-Feng Tai, Taichung (TW); Hsiao-Chun Huang, Taichung (TW); Chun-Hung Lu, Taichung (TW); Hsi-Chang Hsu, Taichung (TW); Shih-Ching Chen, Taichung (TW)

(21) Appl. No.: 16/216,621

(22) Filed: Dec. 11, 2018

Related U.S. Application Data
(62) Division of application No. 14/471,505, filed on Aug. 28, 2014.

(30) Foreign Application Priority Data
Jul. 3, 2014 (TW) 103122955

(51) Int. Cl. H01L 23/544; H01L 23/00; H01L 21/68; H01L 21/56

(52) U.S. Cl. CPC H01L 23/544; H01L 23/3128; H01L 21/682; H01L 24/97; H01L 21/561; H01L 24/19; H01L 2224/05563; H01L 2224/05569; H01L 2224/02331; H01L 2224/02372; H01L 2224/05073; H01L 2224/0401; H01L 2224/05573; H01L 2224/05025; H01L 2223/54453; H01L 2224/12105; H01L 2224/04105; H01L 21/568; H01L 24/96

(57) ABSTRACT

A method for fabricating a package structure is provided, which includes the steps of: providing a base portion having at least an electronic element embedded therein and at least a positioning unit formed around a periphery of the electronic element, wherein the positioning unit protrudes from or is flush with a surface of the base portion; and forming at least a circuit layer on the surface of the base portion and the electronic element. The circuit layer is aligned and connected to the electronic element through the positioning unit.

### BACKGROUND OF THE INVENTION

### 1. Field of the Invention

The present invention relates to package structures and fabrication methods thereof, and more particularly, to a package structure having a positioning structure and a fabrication method thereof.

### 2. Description of Related Art

Along with the rapid development of electronic industries, electronic products are developed toward the trend of multi-function and high performance. Accordingly, wafer level packaging (WLP) technologies have been developed to meet the miniaturization requirement of semiconductor packages.

FIGS. 1A through 1F are schematic cross-sectional views showing a method for fabricating a wafer level fan-out semiconductor package 1 according to the prior art.

Referring to FIG. 1A, a thermal release tape 11 is formed on a carrier 10, and then a plurality of semiconductor elements 12 are disposed on the thermal release tape 11. Each of the semiconductor elements 12 has an active surface 12a with a plurality of electrode pads 120 and an inactive surface 12b opposite the active surface 12a. The semiconductor elements 12 are attached to the thermal release tape 11 via the active surfaces 12a thereof.

Referring to FIG. 1B, an encapsulant 13 is formed by lamination on the thermal release tape 11 for encapsulating the semiconductor elements 12.

Referring to FIGS. 1C and 1C′, another carrier 10′ is disposed on the encapsulant 13 and then a curing process is performed to cure the encapsulant 13. During the curing process, the thermal release tape 11 is heated and loses its adhesive property. As such, the thermal release tape 11 and the carrier 10 are removed to expose the active surfaces 12a of the semiconductor elements 12. Then, a plurality of positioning marks K, X, Y are marked on a surface of the encapsulant 13 around peripheries of the semiconductor elements 12. For example, each of the positioning marks has a cross shape.

Referring to FIGS. 1D through 1E, an RDL (Redistribution Layer) process is performed. The RDL process involves forming a plurality of open areas (not shown) in a photoresist layer (not shown) by exposure and development alignment technologies, forming a plurality of redistribution layers 14a, 14b in the open areas on the encapsulant 13 and the active surfaces 12a of the semiconductor elements 12, and removing the photoresist layer. Each of the redistribution layers 14a, 14b has a dielectric portion 140 and a circuit portion 141 stacked on one another. The circuit portion 141 has a plurality of conductive vias 142 formed in the dielectric portion 140 and electrically connected to the electrode pads 120 of the electronic elements 12.

During attachment of the semiconductor elements 12 and lamination of the encapsulant 13 on the thermal release tape 11, a positional deviation easily occurs to the semiconductor elements 12. Therefore, the exposure alignment technologies use the positioning marks K, X, Y of FIG. 1C as exposure alignment targets to accurately align the redistribution layers 14a, 14b so as to cause the redistribution layers 14a, 14b to be electrically connected to the electrode pads 120 through the conductive vias 142. As such, the accuracy of alignment and connection of the conductive vias 142 is not adversely affected by positional deviation of the semiconductor elements 12.

Referring to FIG. 1F, an insulating layer 15 is formed on the redistribution layer 14b. By using exposure and development alignment technologies (for example, using positioning marks K″ of FIG. 1C), the uppermost circuit portion 141 is partially exposed from the insulating layer 15 for mounting a plurality of conductive elements 16 such as solder balls. Thereafter, a package singulation process is performed along a cutting path S to form a plurality of semiconductor packages 1.

However, in the above-described fabrication method of the semiconductor package 1, the positioning marks K, K′, K″ are difficult to be read by an exposure device due to an interference of the circuit portions 141 made of a metal material. As such, an alignment error easily occurs between the redistribution layers 14a, 14b. The more the number of the redistribution layers 14a, 14b, the bigger the alignment error is.

Referring to FIG. 1F′, as the number of the redistribution layers 14a, 14b increases, the alignment error, i.e., the positional deviation accumulates. The exposure alignment process of each stack layer incurs an accumulation of the alignment error of the semiconductor package 1. For example, three stack layers, i.e., the insulating layer 15 and the two redistribution layers 14a, 14b, lead to a total alignment error that is the sum of three alignment errors e. Therefore, the semiconductor package 1 has a final area size of a predetermined area size L plus the sum of the alignment error e of each layer, i.e., L+6e. Therefore, the size of the semiconductor package 1 is greatly increased. Further, the difficulty in singulation is increased since the width of the cutting path of the semiconductor package 1 is reduced. Furthermore, the number of the semiconductor elements 12 the can be disposed on the carrier 10 is reduced and hence the utilization of the carrier 10 is reduced.

Therefore, how to overcome the above-described drawbacks has become critical.

### SUMMARY OF THE INVENTION

In view of the above-described drawbacks, the present invention provides a method for fabricating a package structure, which comprises the steps of: providing a base portion having opposite first and second surfaces, wherein at least an electronic element is embedded in the base portion and has an active surface having a plurality of electrode pads and an inactive surface opposite to the active surface, and at least a positioning unit is formed around a periphery of the electronic element and protrudes from or is flush with the first surface of the base portion; and forming at least a circuit layer on the first surface of the base portion and the electronic element, wherein the circuit layer is aligned and connected to the electronic element through the positioning unit.

In an embodiment, forming the circuit layer comprises: forming a resist layer on the first surface of the base portion, the positioning unit and the electronic element; forming a plurality of open areas in the resist layer corresponding in position to the electronic element, wherein the open areas are positioned through the positioning unit; forming the circuit layer in the open areas of the resist layer; and removing the resist layer.

After forming the circuit layer, the method can further comprise performing a package singulation process to remove the positioning unit.

The present invention further provides a positioning structure, which comprises: a base portion having opposite first and second surfaces; and at least a positioning unit in contact with the base portion, the positioning unit protruding from or being flush with the first surface of the base portion.

The present invention also provides a package structure, which comprises: at least one of the above-described positioning structure; and at least an electronic element embedded in the base portion and having an active surface having a plurality of electrode pads and an inactive surface opposite the active surface.

The above-described package structure can further have at least a circuit layer formed on the first surface of the base portion and the electronic element, wherein the circuit layer is aligned and connected to the electronic element through the positioning unit.

In the above-described package structure and fabrication method thereof, the circuit layer can have a dielectric portion and a circuit portion bonded to the dielectric portion. The active surface of the electronic element can be exposed from the first surface of the base portion and the electrode pads can be electrically connected to the circuit layer. The electronic element can be an active element, a passive element or a combination thereof.

In the above-described package structure and fabrication method thereof, the positioning unit can comprise a metal material or a non-metal material.

In the above-described package structure and fabrication method thereof, if the positioning unit protrudes from the first surface of the base portion, the circuit layer can have an uneven portion formed corresponding in position to the positioning unit so as to allow the circuit layer to be aligned and connected to the electronic element through the positioning unit.

In the above-described package structure and fabrication method thereof, if the positioning unit is flush with the first surface of the base portion, the positioning unit can be made of a material different from that of the base portion so as to allow the circuit layer to be aligned and connected to the electronic element through the positioning unit.

In the above-described package structure and fabrication method thereof, the positioning unit can be a block protruding from the first surface of the base portion. Further, the positioning unit can be partially embedded under the first surface of the base portion.

In the above-described package structure and fabrication method thereof, the positioning unit can be a block flush with the first surface of the base portion.

In the above-described package structure and fabrication method thereof, the positioning unit can have a positioning base in contact with the base portion and a positioning portion formed on the positioning base.

The positioning base can be a block protruding from the first surface of the base portion.

The positioning base can be partially embedded under the first surface of the base portion.

The positioning base can be embedded in and flush with the first surface of the base portion. The positioning portion can be an opening recessed from the first surface of the base portion. The opening can be formed by etching the positioning base. Forming the positioning unit can comprise: providing a positioning base having an opening; and embedding the positioning base under the first surface of the base portion, with the opening exposed and recessed from the first surface of the base portion.

The positioning base can be a metal block or a non-metal block. The positioning portion can comprise a positioning pad. The positioning portion can be made of a metal material, an insulating material, a semiconductor material or a combination of at least two of them.

According to the present invention, at least a positioning unit is formed to protrude or recess from or be flush with a surface of a base portion. As such, during formation of a plurality of circuit layers, the positioning unit facilitates to form a plurality of open areas in a resist layer corresponding in position to an electronic element. In addition, the position of the positioning unit is easily detected by an aligning device. Therefore, each of the circuit layers can be aligned at a same position so as to overcome the conventional drawbacks.

### BRIEF DESCRIPTION OF DRAWINGS

FIGS. 1A through 1F are schematic cross-sectional views showing a method for fabricating a semiconductor package according to the prior art, wherein FIG. 1C′ is a top view of FIG. 1C, and FIG. 1F′ is a partially top view of FIG. 1F;

FIGS. 2A through 2D are schematic cross-sectional views showing a method for fabricating a package structure according to the present invention, wherein FIGS. 2A′ and 2A″ are top views showing different embodiments of FIG. 2A, and FIGS. 2C-2 and 2C-3 cross-sectional views showing different embodiments of FIG. 2C-1;

FIGS. 3A through 3E are schematic cross-sectional views showing a method for fabricating a package structure according to a second embodiment of the present invention;

FIGS. 4A through 4D are schematic cross-sectional views showing a method for fabricating a package structure according to a third embodiment of the present invention, wherein FIG. 4A′ shows another embodiment of FIG. 4A;

FIGS. 5-1 through 5-6 are partially enlarged cross-sectional views showing different embodiments of a positioning structure of the present invention;

FIGS. 6 and 6′ are schematic top views showing different embodiments of a positioning portion of the positioning structure of the present invention; and

FIG. 7 is a schematic cross-sectional view showing a method for fabricating a package structure according to a fourth embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “first”, “second”, “on”, “a” etc. are merely for illustrative purposes and should not be construed to limit the scope of the present invention.

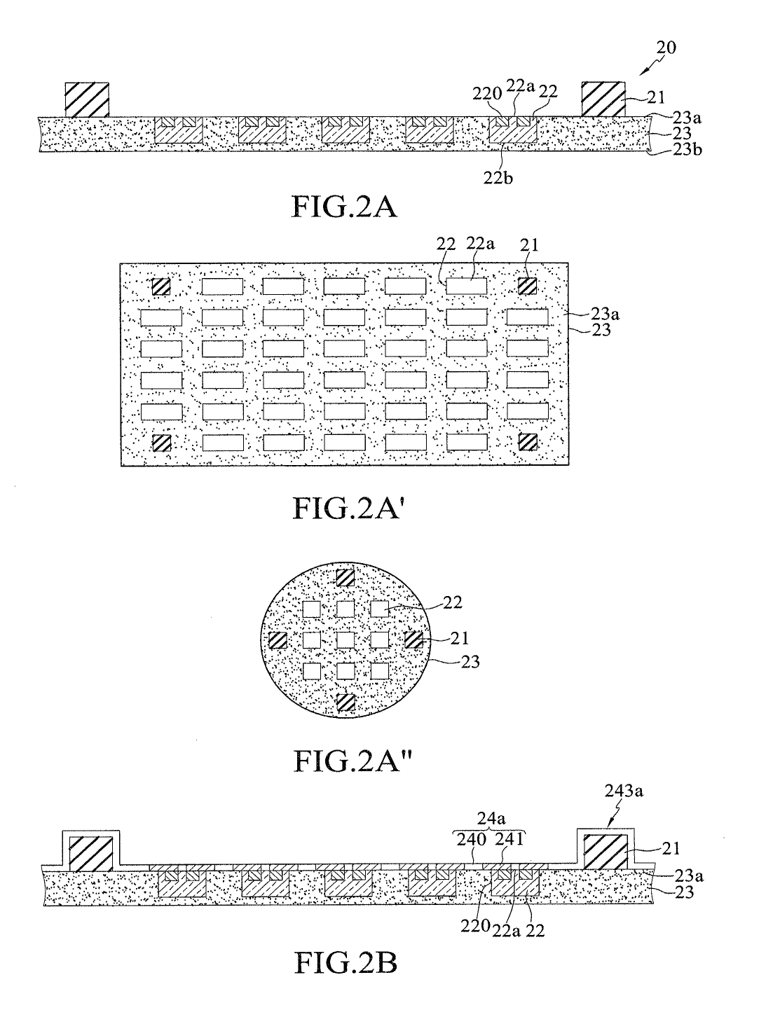

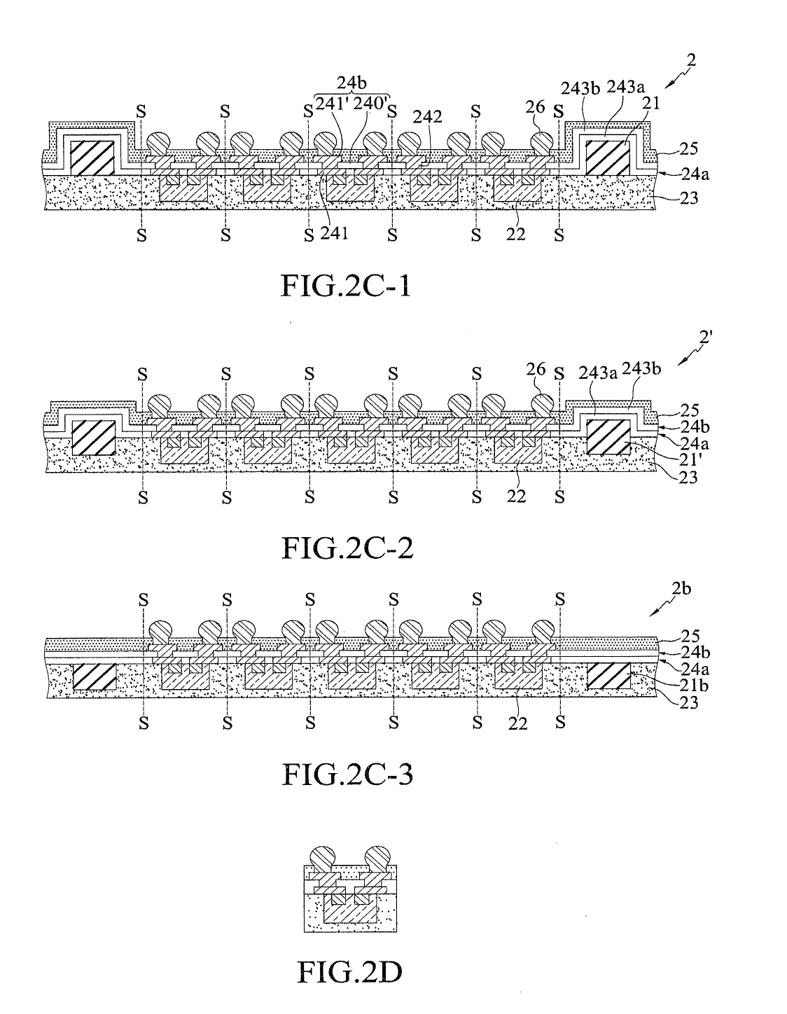

FIGS. 2A through 2D are schematic cross-sectional views showing a method for fabricating a package structure 2 according to a first embodiment of the present invention.

Referring to FIG. 2A, a package 20 is provided. The package 20 has a base portion 23, a plurality of electronic elements 22 embedded in the base portion 23, and a plurality of positioning units 21 formed on the base portion 23 around peripheries of the electronic elements 22. The base portion 23 has opposite first and second surfaces 23a, 23b, and the positioning units 21 protrude from the first surface 23a of the base portion 23.

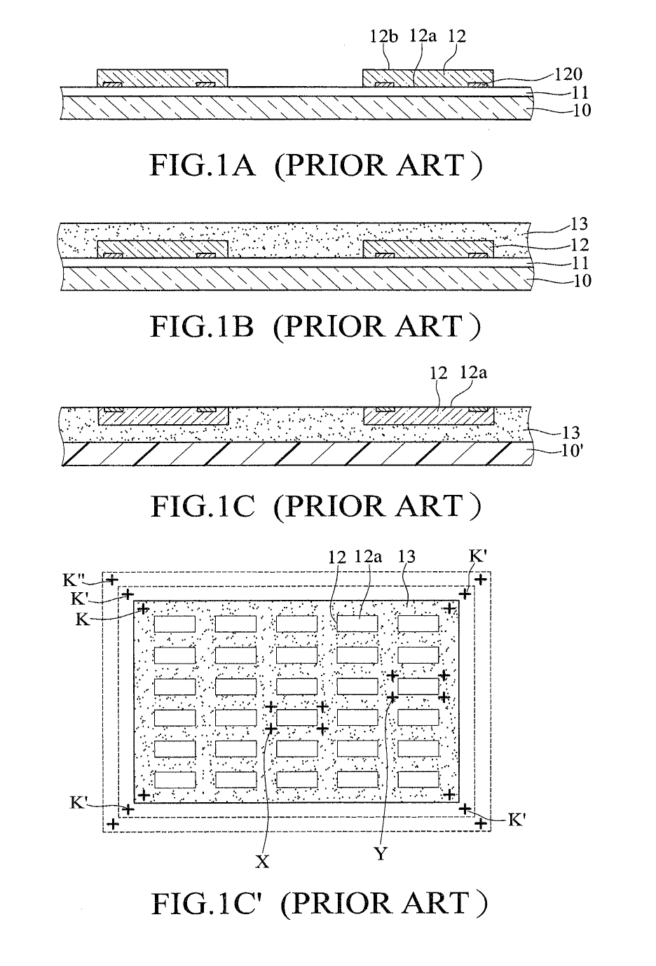

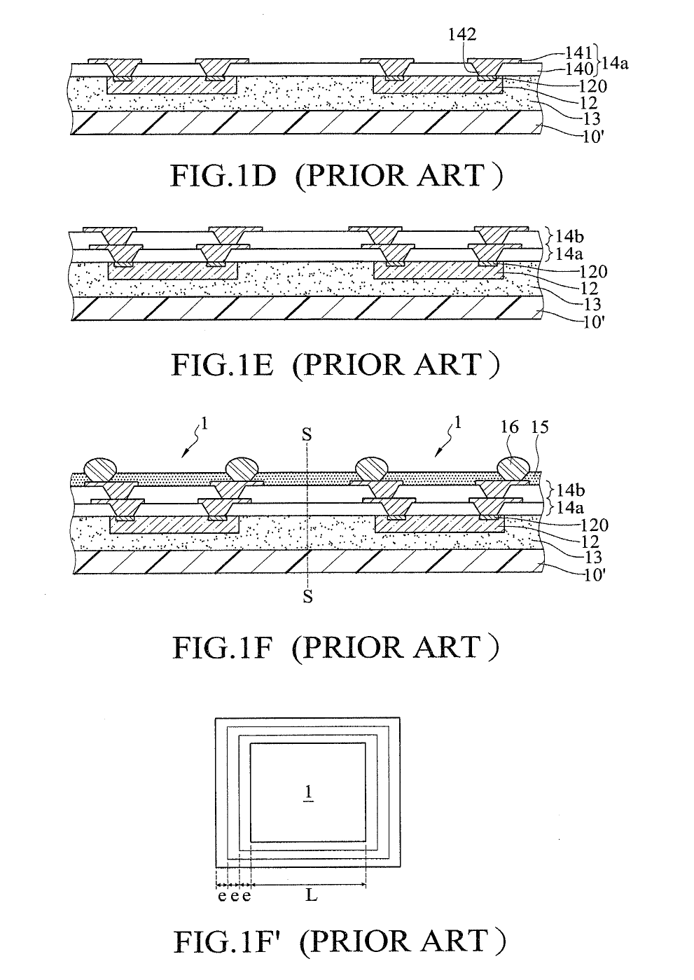

In the present embodiment, the processes of the base portion 23 and the electronic elements 22 are similar to the processes of FIGS. 1A through 1C (the carrier is omitted in FIG. 2A). Then, referring to FIG. 2A′, four blocks are formed on corners of the first surface 23a of the base portion 23 to serve as the positioning units 21. As such, the package 20 is obtained. In particular, at least one positioning unit 21 is provided to facilitate correction of the position of the electronic elements 22 and circuit alignment in subsequent processes. Each of the positioning units 21 has, but not limited to, a circular shape, a cross shape, a rectangular shape, a diamond shape and so on.

Further, each of the positioning units 21 comprises a metal material or a non-metal material. The base portion 23 is made of an insulating material such as ceramic, a dielectric material, a dry film, a liquid epoxy resin, an organic material such as an ABF (Ajinomoto Build-up Film) resin, or a dry film polymer material.

Each of the electronic elements 22 has an active surface 22a with a plurality of electrode pads 220 and an inactive surface 22b opposite to the active surface 22a. The active surface 22a of the electronic element 22 is exposed from the first surface 23a of the base portion 23. Further, the electronic element 22 is a semiconductor element or a passive element.

The electronic elements 22 and the positioning units 21 are arranged in, for example, a rectangular shaped array (panel form) of FIG. 2A′ or a circular shaped array (wafer form) of FIG. 2A″.

Referring to FIG. 2B, an RDL (Redistribution Layer) process is performed to form a first circuit layer 24a on the first surface 23a of the base portion 23 and the active surfaces 22a of the electronic elements 22. The first circuit layer 24a has a plurality of protruding uneven portions 243a formed corresponding in position to the positioning units 21 so as to allow the first circuit layer 24a to be aligned and connected to the electronic elements 22 through the positioning units 21.

In the present embodiment, the first circuit layer 24a has a first dielectric portion 240 formed on the first surface 23a of the base portion 23 and a first circuit portion 241 embedded in the first dielectric portion 240 and electrically connected to the electrode pads 220 of the electronic elements 22.

In particular, forming the circuit layer includes: (a) patterning a dielectric layer (i.e., forming the first dielectric portion 240); (b) forming a seed layer (not shown) on the dielectric layer by sputtering; (c) forming a photoresist layer (not shown) on the seed layer and patterning the photoresist layer; (d) forming a copper layer on the seed layer by electroplating, thereby forming the first circuit portion 241; and (e) removing the photoresist layer and the seed layer under the photoresist layer.

Therefore, before the photoresist layer is patterned, an alignment process needs to be performed by using the positioning units 21 so as to define the exposure pattern of the photoresist layer. To form a number of n circuit layers (n≤1), the steps of (a) through (e) need to be repeated and consequently, a number of n alignment processes are required to define a number of n patterned photoresist layers.

Further, it should be noted that the positioning units 21 are not limited to the four corners and may be formed at other positions.

Referring to FIG. 2C-1, another RDL process is performed to form a second circuit layer 24b on the first circuit layer 24a. The second circuit layer 24b has a plurality of protruding uneven portions 243b formed corresponding in position to the uneven portions 243a of the first circuit layer 24a so as to allow the second circuit layer 24b to be aligned and connected to the first circuit layer 24a through the protruding uneven portions 243b. As such, a package structure 2 having a positioning function is formed.

In the present embodiment, the second circuit layer 24b has a second dielectric portion 240′ formed on the first dielectric portion 240, and a second circuit portion 241′ stacked on the second dielectric portion 240′ and having a plurality of conductive vias 242 formed in the second dielectric portion 240′ so as to be electrically connected to the first circuit portion 241. As such, the electronic elements 22 are electrically connected to the second circuit layer 24b.

Then, an insulating layer 25 is formed on the second circuit layer 24b and the second circuit portion 241′ is partially exposed from the insulating layer 25 for mounting a plurality of conductive elements 26 such as solder balls.

In another embodiment, referring to a package structure 2′ of FIG. 2C-2, each of the positioning units 21′ is partially embedded under the first surface 23a of the base portion 23.

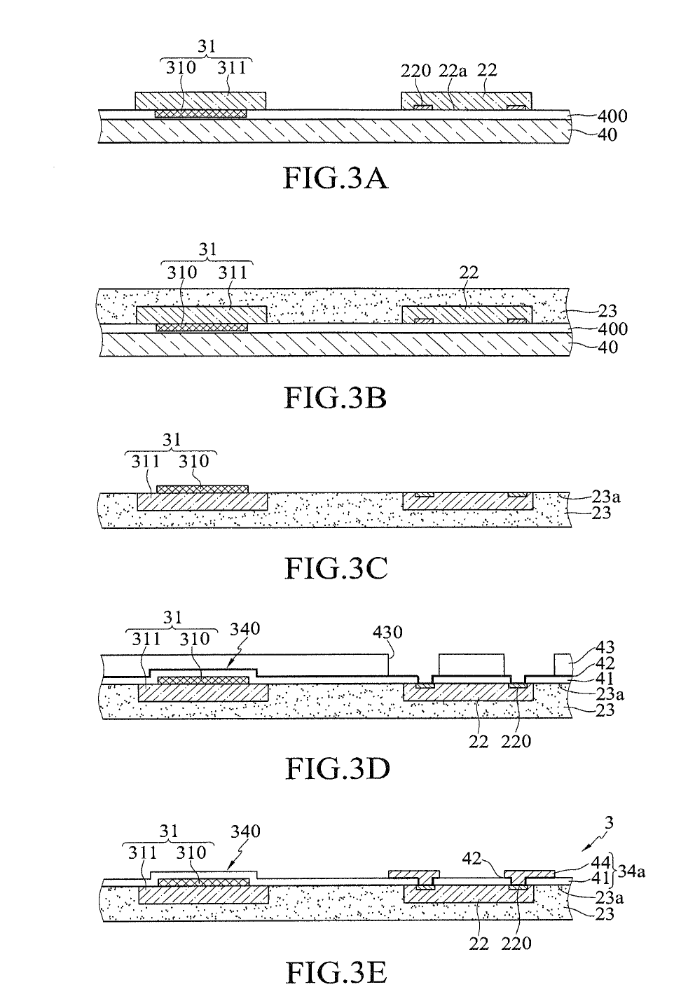

In another embodiment, referring to a package structure 2b of FIG. 2C-3, the positioning units 21b are flush with the first surface 23a of the base portion 23. In particular, the positioning units 21b are blocks embedded in and flush with the first surface 23a of the base portion 23.

Therefore, during fabrication of the circuit layers, although the dielectric material is not transparent, since the positioning units 21, 21′ protrude from the first surface 23a of the base portion 23, the positioning units 21, 21′ can be easily identified by a mask aligner, stepper or laser direct imager according to a height difference and used as reference targets for exposure alignment.

Further, for a multi-circuit layered process, each of the circuit layers is formed with a plurality of uneven portions 243a, 243b corresponding in position to the positioning units 21, 21′. As such, each photoresist layer is aligned at a same position. Therefore, the present invention avoids accumulation of alignment errors as in the prior art and hence overcomes the conventional drawbacks of a great increase of the package size, an increased difficulty in singulation and a reduced utilization of the carrier.

Furthermore, if the positioning units 21b are completely embedded in and flush with the first surface 23a of the base portion 23, the positioning units 21b can be made of a material different from that of the base portion 23. By registering and scanning different materials, the mask aligner, stepper, or laser direct imager can easily identify the positioning units as reference targets for circuit layer alignment.

Referring to FIG. 2D, a package singulation process is performed along cutting paths S of FIG. 2C-1, FIG. 2C-2 or FIG. 2C-3 so as to remove the positioning units 21, 21′, 21b and the uneven portions 243a, 243b. As such, a plurality of package units are formed.

FIGS. 3A through 3E are schematic cross-sectional views showing a method for fabricating a package structure 3 according to a second embodiment of the present invention. In the present embodiment, each of the positioning units 31 has a positioning base 311 and at least a positioning portion 310 formed on the positioning base 311. The positioning units 31 and at least an electronic element 22 are embedded in a base portion 23 through a same process.

Referring to FIG. 3A, at least a positioning unit 31 and the electronic element 22 are disposed on a bonding layer 400 of a carrier 40.

In the present embodiment, the positioning base 311 is a dummy die having no electrical function or a semiconductor die having a certain function. The positioning base 311 has a positioning pad serving as the positioning portion 310. The positioning portion 310 is embedded in the bonding layer 400.

The positioning portion 310 is made of electroplated aluminum, electroplated copper, a coated and etched metal material, an insulating material such as polyimide patterned by photolithography, a semiconductor material or a combination of at least two of them.

The positioning base 311 and the positioning portion 310 can be made of same or different materials.

Referring to FIG. 3B, the base portion 23 is formed on the bonding layer 400 for encapsulating the positioning base 311 and the electronic element 22.

Referring to FIG. 3C, the bonding layer 400 and the carrier 40 are removed to expose the active surface 22a of the electronic element 22. The positioning base 311 is flush with the first surface 23a of the base portion 23, and the positioning portion 310 protrudes from the first surface 23a of the base portion 23.

Referring to FIG. 3D, a patterned dielectric portion 41 is formed on the first surface 23a of the base portion 23, and a seed layer 41 is formed on the dielectric portion 41 by sputtering. Then, a photoresist layer 43 is formed on the seed layer 42 and patterned to form a plurality of open areas 430 in communication with the electrode pads 220 of the electronic element 22.

Referring to FIG. 3E, by using the seed layer 42 as a current conductive path, a copper electroplating process is performed to form a circuit portion 44 in the open areas 430 of the photoresist layer 43. Then, the photoresist layer 43 and the seed layer 42 under the photoresist layer 43 are removed. The dielectric portion 41 and the circuit portion 44 form a circuit layer 34a. The circuit layer 34a has a protruding uneven portion 340 formed corresponding in position to the positioning portion 310.

Further, when the circuit portion 44 is formed, a metal material can be formed on the positioning portion 310. Therefore, the uneven portion 340 can be made of a metal material, a dielectric material or a combination thereof.

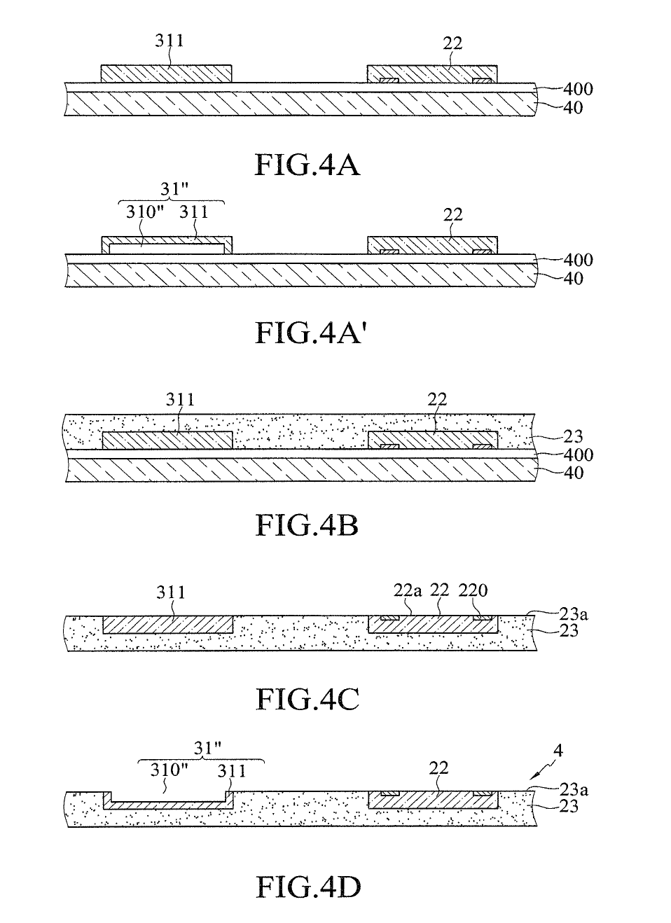

FIGS. 4A through 4D are schematic cross-sectional views showing a method for fabricating a package structure 4 according to a third embodiment of the present invention. The third embodiment differs from the second embodiment in that the positioning portion is an opening 310″ and the positioning unit 31″ is recessed with respect to the first surface 23a of the base portion 23. The opening 310″ has a quadrilateral shape, a circular shape, an oval shape or any other geometric shape.

Referring to FIG. 4A, a positioning base 311 and at least an electronic element 22 are disposed on a bonding layer 400 of a carrier 40.

Referring to FIG. 4B, a base portion 23 is formed on the bonding layer 400 for encapsulating the positioning base 311 and the electronic element 22.

Referring to FIG. 4C, the bonding layer 400 and the carrier 40 are removed to expose the active surface 22a of the electronic element 22. Also, the positioning base 311 is flush with the first surface 23a of the base portion 23.

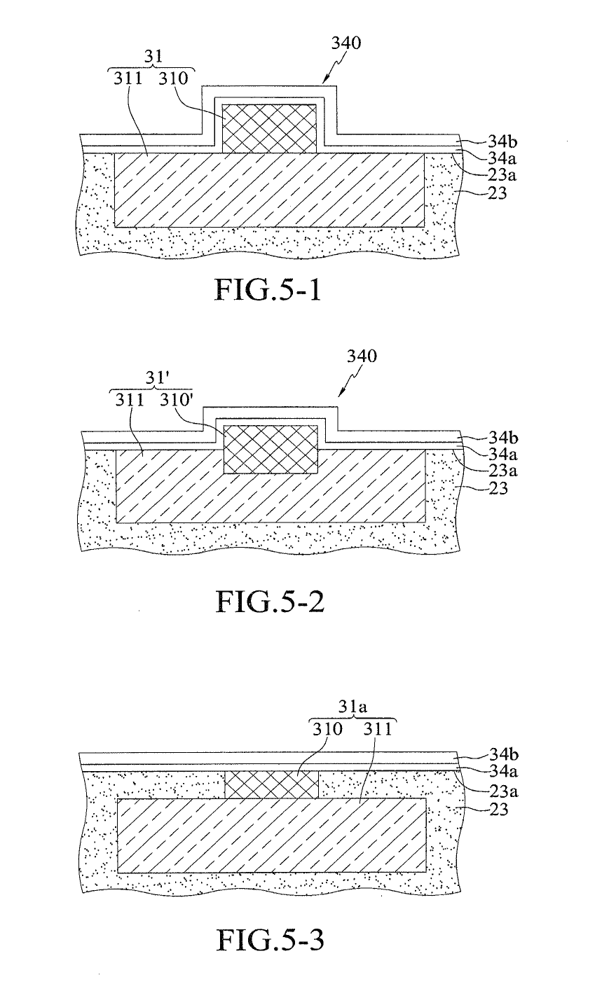

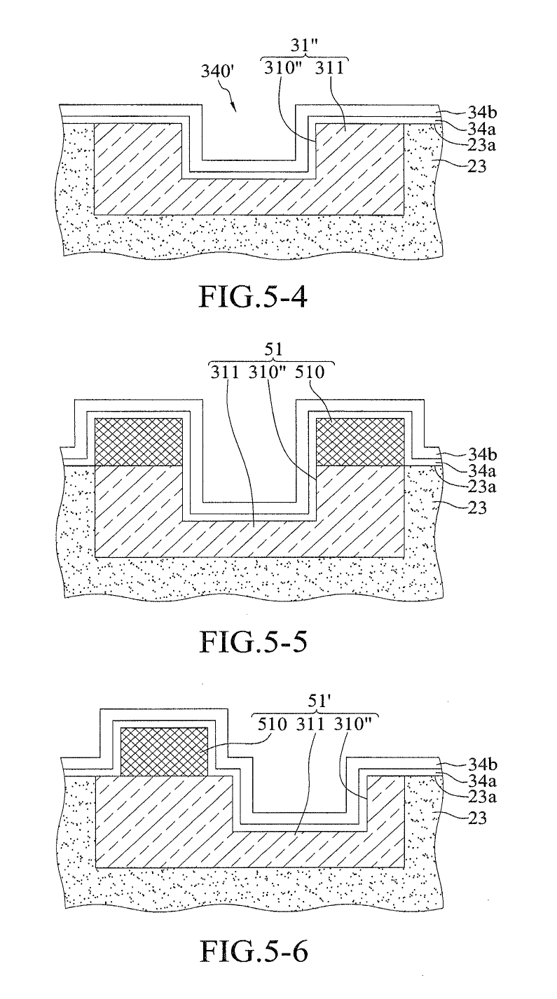

Referring to FIG. 4D, the positioning base 311 is etched to form the opening 310″. The opening 310″ is exposed from the first surface 23a of the base portion 23. Thereafter, when circuit layers 34a, 34b are formed, a recessed uneven portion 340′ is formed corresponding in position to the opening 310″, as shown in FIG. 5-4.

In an alternative embodiment, referring to FIG. 4A′, a positioning unit 31″ (i.e., a block) having an opening 310″ is provided. The positioning unit 31″ and the electronic elements 22 are embedded in the base portion 23 through the same process. That is, the positioning unit 31″ and the electronic element 22 are disposed on the bonding layer 400 of the carrier 40. As such, after the bonding layer 400 and the carrier 40 are removed, the opening 310″ is directly exposed and recessed from the first surface 23a of the base portion 23.

In the second embodiment, the positioning portion 310 of the positioning unit 31 is positioned on the positioning base 311, as shown in FIG. 5-1. In another embodiment, the positioning portion 310′ of the positioning unit 31′ is partially embedded in the positioning base 311, as shown in FIG. 5-2.

Further, the positioning portion 310 of the positioning unit 31a can be flush with the first surface 23a of the base portion 23, as shown in FIG. 5-3.

In a further embodiment, the positioning portion of the positioning unit 31″ is an opening 310″ recessed from the first surface 23a of the base portion 23 and therefore the positioning unit 31″ is recessed with respect to the first surface 23a of the base portion 23, as shown in FIG. 5-4.

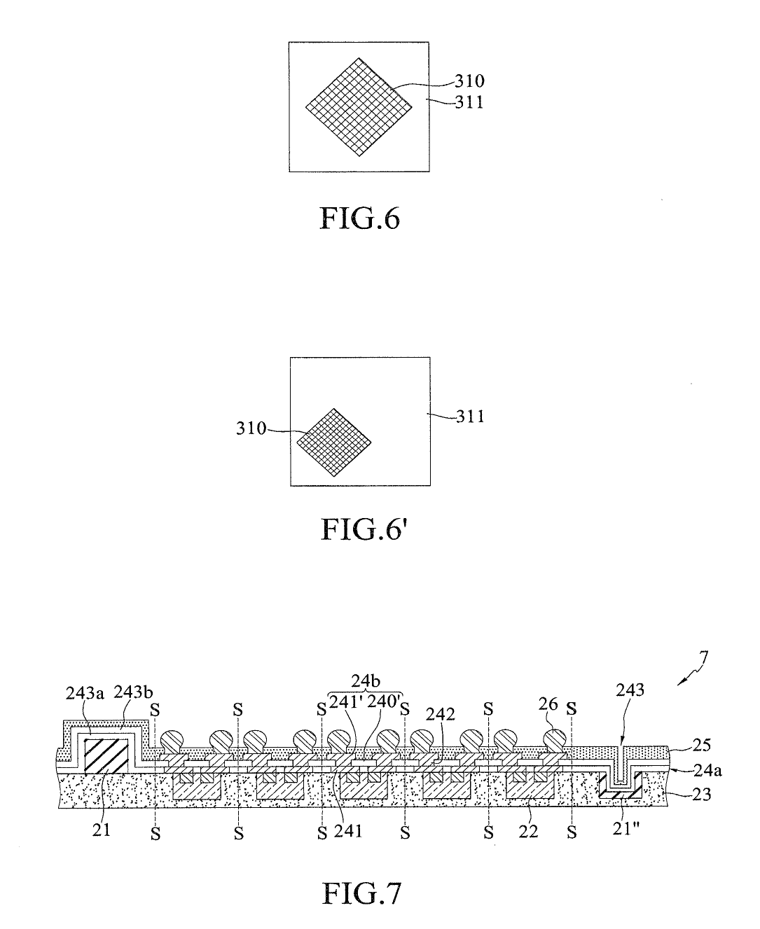

Furthermore, various examples can be provided according to the above-described positioning structures. In an example, referring to FIG. 5-5, the positioning unit 51 has a positioning portion consisting of a positioning pad 510 and an opening 310″ that are in connection with one another. In another example, referring to FIG. 5-6, the positioning unit 51′ has a positioning portion consisting of a positioning pad 510 and an opening 310″ that are separated from one another.

The positioning base 311 of the second and third embodiments can be disposed by referring to the position of the positioning units 21, 21′, 21b of the first embodiment.

Further, the positioning portion 310 or the opening 310″ of the second and third embodiments can be located at the center of the surface of the positioning base 311, as shown in FIG. 6. Alternatively, the positioning portion 310 or the opening 310″ can be located at a position other than the center of the surface of the positioning base 311, as shown in FIG. 6′.

Furthermore, a plurality of positioning pads (as shown in FIG. 5-5) can be provided on a single positioning base 311. Each of the positioning pads can have a quadrilateral shape, a circular shape, an oval shape or any other geometric shape.

In other embodiments, the positioning base 311 can be a metal block or an insulating block made of ceramic or a dielectric material.

FIG. 7 is a schematic cross-sectional view showing a method for fabricating a package structure 7 according to a fourth embodiment of the present invention. In the present embodiment, different types of positioning units are provided.

Referring to FIG. 7, the package structure 7 has a positioning unit 21 protruding from the first surface 23a of the base portion 23 and a positioning unit 21″ recessed from the first surface 23a of the base portion 23. In other embodiments, the positioning units of FIGS. 2C-1 through 2C-3 and FIGS. 5-1 through 5-6 can be combined to provide various configurations.

The present invention provides a positioning structure, which has: a base portion 23 having opposite first and second surfaces 23a, 23b; and at least a positioning unit 21, 21′, 21″, 21b, 31, 31′, 31″, 31a, 51, 51′ in contact with the base portion 23. The present invention further provides a package structure 2, 2′, 2b, 3, 4, 7, which has: the above-described positioning structure; and at least an electronic element 22 embedded in the base portion 23.

The electronic element 22 has an active surface 22a having a plurality of electrode pads 220 and an inactive surface 22b opposite the active surface 22a. The active surface 22a of the electronic element 22 can be exposed from the first surface 23a of the base portion 23. The electronic element 22 can be an active element, a passive element or a combination thereof.

The positioning unit 21, 21′, 21″, 21b, 31, 31′, 31″, 31a, 51, 51′ is positioned around a periphery of the electronic element 22 and protrudes from or is flush with the first surface 23a of the base portion 23. The positioning unit 21, 21′, 21″, 21b, 31, 31′, 31″, 31a, 51, 51′ can include a metal material or a non-metal material.

In an embodiment, the positioning unit 21, 21′ is a block protruding from the first surface 23a of the base portion 23. Further, the positioning unit 21′ can be partially embedded under the first surface 23a of the base portion 23.

In an embodiment, the positioning unit 21b, 21″ is a block completely embedded in and flush with the first surface 23a of the base portion 23.

In an embodiment, the package structure 2, 2′, 2″ further has a first circuit layer 24a and a second circuit layer 24b formed on the first surface 23a of the base portion 23 and the active surface 22a of the electronic element 22. The first circuit layer 24a and the second circuit layer 24b are aligned and connected to the electronic element 22 through the positioning unit 21, 21′, 21″, 21b. The first circuit layer 24a has a first dielectric portion 240 and a first circuit portion 241 bonded to the first dielectric portion 240. The second circuit layer 24b has a second dielectric portion 240′ and a second circuit portion 241′ bonded to the second dielectric portion 240′. The first and second circuit portions 241, 241′ are electrically connected to the electronic element 22.

Therefore, if the positioning unit 21, 21′, 31″ protrudes from the first surface 23a of the base portion 23, the first and second circuit layers 24a, 24b have uneven portions 243a, 243b, 340′ formed corresponding in position to the positioning unit 21, 21′, 31″ so as to allow the first and second circuit layers 24a, 24b to be aligned and connected to the electronic element 22 through the positioning unit 21, 21′, 31″.

If the positioning unit 21b is flush with the first surface 23a of the base portion 23, the positioning unit 21b comprises a material different from that of the base portion 23 so as to allow the first and second circuit layers 24a, 24b to be aligned and connected to the electronic element 22 through the positioning unit 21b.

In an embodiment, the positioning unit 31, 31′, 31″, 31a, 51, 51′ has a positioning base 311 and a positioning portion 310, 310′, 310″ formed on the positioning base 311. The positioning base 311 is a metal block or a non-metal block.

The positioning base 311 can be a block protruding from the first surface 23a of the base portion 23, a block partially embedded under the first surface 23a of the base portion 23, or a block embedded in and flush with the first surface 23a of the base portion 23.

The positioning portion 310, 310′ can be at least a positioning pad, which can be made of a metal material, an insulating material, a semiconductor material or a combination of at least two of them. Alternatively, the positioning portion can be an opening 310″ recessed from the first surface 23a of the base portion 23.

According to the present invention, at least a positioning unit is formed to protrude from or be flush with a surface of a base portion. As such, during formation of a plurality of circuit layers, each photoresist layer is aligned at a same position through the positioning unit so as to facilitate to form a plurality open areas in the photoresist layer by exposure, thereby overcoming the conventional drawback of accumulation of alignment errors and causing the circuits to be effectively electrically connected to the electronic element.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

1-22. (canceled)

23: A positioning structure, comprising:
a base portion having opposite first and second surfaces; and
at least a positioning unit in contact with the base portion, the positioning unit protruding from or being flush with the first surface of the base portion.

24: The structure of claim 23, wherein the positioning unit has a positioning base in contact with the base portion and a positioning portion formed on the positioning base.

25-26. (canceled)

27: The structure of claim 24, wherein the positioning base is embedded in and flush with the first surface of the base portion.

28-31. (canceled)

32: The structure of claim 23, wherein the positioning unit comprises a metal material or a non-metal material.

33-34. (canceled)

35: The structure of claim 23, wherein the positioning unit is a block flush with the first surface of the base portion.

36-42. (canceled)
